(19) United States
(12) Patent Application Publication
(10) Pub. No.: US 2026/0231459 A1
(43) Pub. Date: Aug. 6, 2026

(54) NANOSHEET HEMT STRUCTURES AND METHODS THEREOF

(71) Applicant: Matthew Hartensveld, Geneva, NY (US)

(72) Inventor: Matthew Hartensveld, Geneva, NY (US)

(73) Assignee: NanoTech Strategies LLC, Geneva, NY (US)

(21) Appl. No.: 19/460,011

(22) Filed: Jan. 26, 2026

Related U.S. Application Data
(60) Provisional application No. 63/753,347, filed on Feb. 3, 2025.

(51) Int. Cl. H10D 30/47; H10D 30/00; H10D 30/43; H10D 62/10; H10D 62/60; H10D 62/824; H10D 84/82; H10D 84/83

(52) U.S. Cl. CPC H10D 30/474; H10D 30/43; H10D 30/502; H10D 62/121; H10D 62/60; H10D 62/824; H10D 84/82; H10D 84/832; H10D 62/102

(57) ABSTRACT

A gate-all-around (GAA) high electron mobility transistor (HEMT) architecture is disclosed, comprising a multi-layer III-Nitride structure including alternating n-doped and unintentionally doped (u-doped) layers. Nanosheet or nanowire columns of these layers serve as the device channel, while a wider bandgap barrier shell is deposited to enhance electron confinement and gate control. The n-doped layers may be selectively removed in the channel region by wet or dry etching techniques facilitated by hole injection, enabling normally-off operation. A regrown n-doped region extends the source and drain contacts, reducing contact resistance. The gate, which fully encircles the channel region, may be implemented with either a gate dielectric or a Schottky contact to establish the desired threshold behavior. This structure improves electrostatic control, reduces parasitic leakage, and enables superior power and high-frequency performance compared to conventional planar HEMTs.

This application claims the benefit of U.S. Provisional Patent Application Ser. No. 63/753,347, filed Feb. 3, 2025, which is hereby incorporated by reference in its entirety.

### FIELD

The present disclosure relates generally to semiconductor devices and fabrication methods, and more particularly to III-nitride transistor devices. In various embodiments, the disclosure relates to nanosheet or nanowire high-electron-mobility transistor (HEMT) structures including repeated III-nitride layer stacks and gate-all-around configurations.

### BACKGROUND

III-Nitride materials system has enabled a wide range of commercial applications, including 5G base stations, radar systems, satellite communications, and high-efficiency power conversion. These applications benefit from the unique material properties of III-Nitrides, which conventionally include Al, Ga, and In nitrides. III-Nitride semiconductors are particularly advantageous due to their high breakdown voltage, strong polarization effects, and high electron saturation velocity, making them well-suited for these high-power and high-frequency devices.

Among III-Nitride devices, high electron mobility transistors (HEMTs) have become the standard for RF and power applications due to their ability to support both high electron mobility and large electric fields. The most widely used HEMT structures rely on an AlGaN/GaN heterojunction, where a two-dimensional electron gas (2DEG) forms at the interface due to the combined effects of bandgap differences and polarization-induced charge accumulation. This 2DEG provides a low-resistance channel that enables high-speed operation and efficiency. However, despite these advantages, conventional HEMTs still face limitations that hinder their performance and scalability for next-generation device applications.

A major limitation of conventional AlGaN/GaN HEMTs is their normally-on operation, where the 2DEG is naturally present in the absence of an applied gate bias. This behavior requires a negative gate voltage to switch the device off, which introduces safety concerns, particularly in high-power applications, where fail-safe normally-off operation is desirable. Various techniques have been explored to achieve normally-off behavior, including recessed-gate structures, p-GaN gate technology, and fluoride ion implantation near the channel. In the recessed-gate approach, selective etching is used to thin the AlGaN barrier layer under the gate, which can enable normally-off operation but suffers from process variability and threshold voltage instability. The p-GaN gate approach introduces a p-type GaN layer to deplete the 2DEG under zero gate bias, yet this method presents reliability concerns due to gate leakage, threshold voltage drift, and limited scalability. Fluoride ion implantation provides another means of suppressing the 2DEG, but this approach can introduce unwanted temperature sensitivity, which degrades long-term device reliability.

To further improve device performance, FinFET-based HEMTs have been developed, where fin-like structures replace the conventional planar channel. In this architecture, the gate wraps around three sides of the fin, enhancing electrostatic control and enabling normally-off operation. This structure also provides increased current density and improved short-channel characteristics. However, despite these benefits, FinFET-based HEMTs still suffer from high parasitic capacitance, which limits high-frequency performance.

A more advanced approach is the Gate-All-Around (GAA) HEMT architecture, where the gate completely surrounds the nanosheet or nanowire channel. GAA structures offer superior gate control, effectively minimizing short-channel effects and enabling higher frequency operation. Additionally, they provide reduced leakage current and improved power efficiency, making them highly attractive for RF and power applications. However, despite these advantages, the practical realization of GAA HEMTs remains challenging due to fabrication complexities such as precise nanosheet formation, uniform channel formation, and contact resistance reductions. Achieving uniform channel thickness and spacing for ensuring consistent electrical performance has remained the critical challenge.

Compared to competing semiconductor technologies, such as silicon-based FinFETs or GAA-FETs and silicon carbide (SiC) MOSFETs, III-Nitride-based GAA HEMTs have the potential to offer superior power density, higher breakdown voltage, and enhanced high-frequency performance. However, to fully realize these benefits, new device architectures and fabrication techniques are required to overcome the current limitations associated with HEMTs and FinFET-based structures.

Therefore, there is a critical need for an improved III-Nitride transistor architecture that enables normally-off operation, enhances gate control, minimizes parasitic capacitance, and maintains the high electron mobility and power efficiency advantages of conventional HEMTs. The development of a scalable and manufacturable nanosheet-based GAA HEMT could provide the next leap forward in power and RF semiconductor technology, addressing the existing limitations while unlocking new opportunities for high-performance electronics.

### SUMMARY

In various embodiments, a transistor device includes a substrate and a multi-layer structure formed on or above the substrate. The multi-layer structure may include a plurality of repeated stacks, each stack comprising an n-doped III-nitride layer and an unintentionally doped (u-doped) III-nitride layer. One or more of the u-doped III-nitride layers may define at least part of a channel region, which in some embodiments is provided in the form of one or more columns, nanosheets, or nanowires.

In various embodiments, a barrier shell is disposed around at least a portion of the channel region. The barrier shell may comprise a wider bandgap III-nitride material relative to the u-doped III-nitride layer and may be configured to enhance carrier confinement. A source region and a drain region may be electrically coupled to the channel region, and a gate structure may be configured to at least partially surround the channel region to provide a gate-all-around transistor configuration.

In various embodiments, methods of forming such devices include forming the repeated III-nitride layer stacks, defining one or more channel structures from the stacks, and forming the barrier shell, gate structure, and source/drain regions.

### BRIEF DESCRIPTION OF THE DRAWINGS

The figures are schematic and not necessarily to scale; for clarity, certain features may be simplified or omitted, and cross-sections may depict only the active device region.

FIG. 1 is a cross-sectional schematic illustration of an exemplary III-Nitride growth structure on a substrate, depicting the arrangement of the substrate, buffer layers, and multiple epitaxial layers;

FIG. 2 is a top-down schematic view showing the patterned epitaxial layers after selective etching, defining an active device region between the source and drain;

FIG. 3A is a cross-sectional view (taken along a dashed line in FIG. 2) illustrating a nanosheet-type channel configuration;

FIG. 3B is a cross-sectional view (taken along a dashed line in FIG. 2) showing a nanowire channel configuration;

FIG. 3C is a cross-sectional view (taken along a dashed line in FIG. 2) depicting multiple parallel nanosheet columns sharing a common source and drain;

FIG. 4 is a schematic illustration of the formation of a barrier shell on the separated channel structures, enabling gate-all-around (GAA) operation;

FIG. 5 is a perspective view of the device following metallization of the source and drain, including an optional selectively regrown extended region;

FIG. 6A is a cross-sectional view of the channel region illustrating the formation of a gate with a dielectric layer;

FIG. 6B is a cross-sectional view of the channel region illustrating a direct Schottky contact in place of the dielectric layer;

FIG. 7 is a rotated cross-sectional view illustrating the barrier shell and gate along channel region;

FIG. 8A is a perspective view of the final device architecture featuring an interconnecting gate metallization without extended source/drain regions; and

FIG. 8B is a perspective view of the final device architecture featuring an interconnecting gate metallization with the extended source/drain regions.

### DETAILED DESCRIPTION

In the present disclosure, the III-Nitride materials system is utilized to form nanowire, nanosheet, or nanofork structures, upon which additional epitaxial growth and subsequent device fabrication steps are performed to realize gate-all-around (GAA) high electron mobility transistors (HEMTs). The III-Nitride materials conventionally include Al, Ga, and In nitrides, although additional elements such as B or Sc may be incorporated to tailor polarization properties.

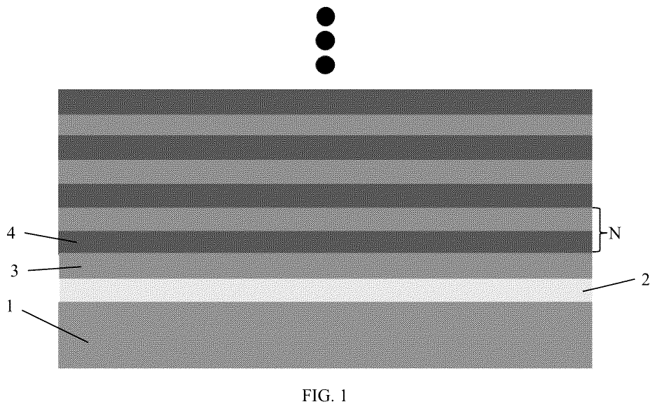

Referring to FIG. 1, a substrate 1 is employed to support epitaxial growth. The substrate 1 may comprise, by way of example, AlGaN, GaN, InGaN, silicon (Si), silicon carbide (SiC), or sapphire. A buffer layer 2 may be formed on the substrate 1 to facilitate an acceptable level of crystal quality for subsequent active layers. The buffer layer 2 can include one or more III-Nitride materials, and may be grown using techniques such as metal-organic chemical vapor deposition (MOCVD), low-pressure chemical vapor deposition (LPCVD), hydride vapor phase epitaxy (HVPE), or molecular beam epitaxy (MBE). In some embodiments, the buffer layer 2 is doped (e.g., with carbon) to provide electrical isolation between and within subsequently fabricated devices. As used herein, the term “active” denotes regions and layers that are electrically engaged in the final device operation.

Following formation of the buffer layer 2, a series of unintentionally doped layers 3 and n-type doped layers 4 are grown. The unintentionally doped layer 3 and n-doped layer 4 may be of the same or different thicknesses between each other, ranging between 5 nm and 300 nm in most embodiments, chosen based on desired current density and device voltage rating. This pair of layers is repeated N times to form a multi-layered structure, where N is an integer selected to optimize device performance. As illustrated by the bracket labeled N in FIG. 1, the n-doped layers 4 and u-doped layers 3 may be repeated N times, where N is an integer. The n-type layers 4 may be doped, for example, with silicon (Si) at a concentration exceeding about 1×10\hat{ }18 cm\hat{ }−3, preferably around 1×10\hat{ }19 cm\hat{ }−3. The unintentionally doped layers 3 (u-doped) typically exhibit native material conductivity from growth, without intentional dopant incorporation; by way of example, an effective doping level of about 1×10\hat{ }15 cm\hat{ }−3 to 5×10\hat{ }16 cm\hat{ }−3 may be employed. In one embodiment, both the n-type layer 4 and the unintentionally doped layer 3 comprise GaN, optionally including varying levels of Al or In. More generally, the n-type and unintentionally doped layers may be formed from an AlInGaN alloy or other suitable III-Nitride material.

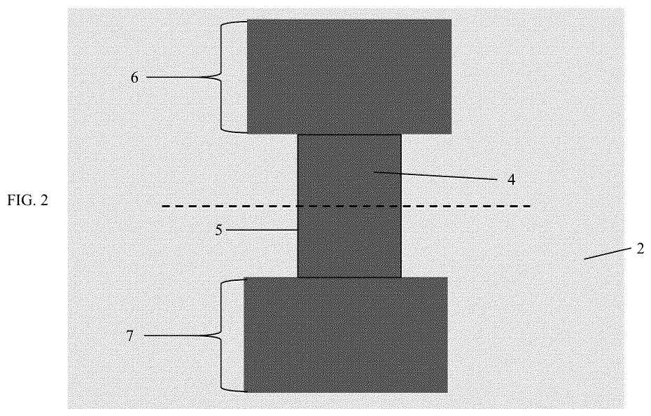

Referring to FIG. 2, which provides a top-down perspective, once the layer pairs are grown, selective patterning and removal steps are performed to define the active device region. These steps may be carried out using dry etching techniques such as reactive ion etching (RIE) or inductively coupled plasma (ICP) etching, among others. The underlying buffer layer 2 or substrate 1 may be exposed during etch processes, and one or more columns of the layer pair stacks are thereby formed, ultimately serving as the channel or active device region 5 between the source 6 and drain 7. In preferred embodiments, the selective patterning and removal steps remove the multi-layer structure in regions laterally adjacent to the one or more columns such that the buffer layer 2 or substrate 1 is exposed outside the active device region, thereby preventing the unintentionally doped layers 3 from forming a continuous lateral conduction path between the source 6 and drain 7. In certain embodiments, the columns may exhibit uniform or varying diameters. Post-etching damage removal techniques, such as wet chemical etching (e.g., hydroxyl-based chemistries), additional dry etching, or thermal annealing, may be employed to mitigate etch damage and further reduce the width of the remaining layer pair structures. The width of the channel region 5 may be as small as 5 nm to as large as 1000 nm in some examples, depending on the device design factors.

Following formation of the patterned structures, a dielectric layer may be deposited to facilitate selective etching of the n-doped layers 4 in all or part of the channel region. This dielectric layer can comprise materials such as Al2O3, Si3N4, SiO2, or HfO2. In some embodiments, the dielectric is selectively etched to expose all or part of the channel region 5 of the transistor, enabling wet chemical removal of the n-doped layers 4 and thereby freeing the unintentionally doped layers 3. Because the source 6 and drain 7 regions often comprise a relatively larger area, the dielectric masking step may be partially or wholly omitted in those regions, with the potential tradeoff of some unwanted etching of the n-doped layers 4 in these areas. To ensure targeted etching of the n-doped layers 4 in the channel region 5 and release of the unintentionally doped layers 3, holes are injected into the n-doped layers 4, either through anodic bias or photoexcitation, thereby promoting selective dissolution.

In one embodiment, the n-doped layer 4 exhibits a smaller bandgap relative to the unintentionally doped layer 3, enabling the use of a light source to generate holes in the n-doped layer 4 via photoexcitation. The presence of holes at the surface facilitates formation of gallium oxides, which may subsequently be dissolved. In a preferred approach, the light source is pulsed or modulated to relax the quasi-Fermi levels, thereby enhancing electron transport at the surface for improved oxide dissolution. Suitable etchants may include hydroxyl-based chemistries, potassium persulfate, hydrofluoric acid, hydrochloric acid, or oxalic acid, which may be employed at concentrations of about 0.01 M, by way of example. A wavelength strongly absorbed by the n-doped layer 4, rather than by the unintentionally doped layer 3, may be used to increase selectivity. Wavelengths may be 254 nm to 450 nm in some examples. External heating may also be applied to accelerate the reaction kinetics.

In another embodiment, an anodic bias is applied to achieve hole injection into the n-doped layer 4, either alone or in conjunction with photoexcitation. Under anodic bias, significant bandgap tuning between the n-doped layer 4 and the unintentionally doped layer 3 may not be required, as the Fermi-level difference resulting from the doping level primarily drives selectivity. A platinum electrode in solution may serve as a reference electrode while the sample is maintained at a positive voltage. As in other embodiments, suitable etchant solutions can include hydroxyl-based chemistries, potassium persulfate, hydrofluoric acid, hydrochloric acid, or oxalic acid at concentrations of about 0.01 M, by way of example. The applied bias may be constant, ramped, pulsed, or alternating, with preferred average voltages typically being below about 100 V, although actual voltages may depend on factors such as electrode spacing, sample size, and contact design. External heating can also be employed to facilitate faster reaction rates.

Following the etching of the n-doped layer 4, one or more cleaning steps may be performed to remove residual etchant chemistries and any remaining portions of the n-doped layer 4 within the channel region 5 between the unintentionally doped layers 3. In certain embodiments, a cleanup etch using dry etching techniques (e.g., reactive ion etching (RIE) or inductively coupled plasma (ICP)) or a hydroxyl-based wet chemical process may be employed to ensure thorough removal. Any dielectric masking layer can be fully removed following the wet etch and clean up steps.

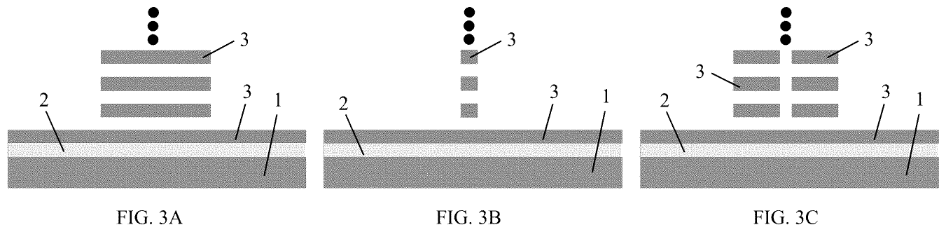

Referring now to FIGS. 3A-3C, cross-sectional views of various channel region 5 geometries are illustrated, where the cross-section location is indicated by the dashed line in FIG. 2. FIGS. 3A-3C are schematic cross-sections through the remaining column structures in the active device region; for clarity, surrounding portions of the multi-layer structure that may be removed down to the buffer layer 2 as described with respect to FIG. 2 are not shown. The final geometry of the channel region may be influenced by both epitaxial growth parameters and the initial dry etch pattern. By way of example, FIG. 3A depicts a nanosheet-type channel structure, FIG. 3B shows a nanowire configuration, and FIG. 3C illustrates multiple parallel nanosheet columns sharing a common source 6 and drain 7.

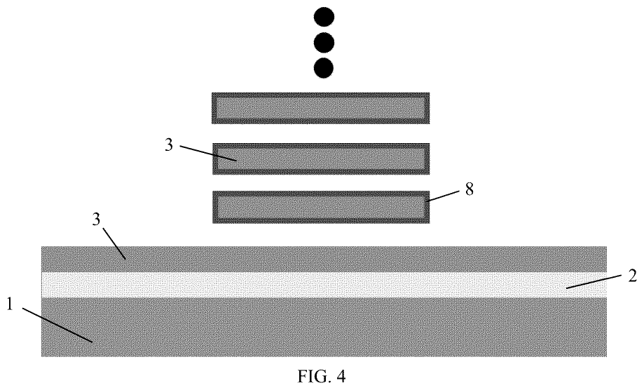

Once the separated unintentionally doped layers 3 are formed, a HEMT structure may be realized by depositing or growing a barrier shell 8 on these layers, as schematically shown in FIG. 4. In some embodiments, the barrier shell 8 is selectively grown on the channel region using a dielectric mask; in other embodiments, it may be uniformly grown and subsequently removed from undesired areas. The length of the barrier shell 8 either spans a bit more than the channel region 5 to overlap the source and drain, or is equal to or greater than the n-doped layer 4 wet chemical etch mask, all to ensure continuous channel conduction. The barrier shell 8 comprises a wider bandgap material than the unintentionally doped layers 3 and may include additional sub-layers, such as a spacer layer. The thickness of the barrier shell 8 can vary anywhere from 5 nm to 300 nm in some embodiments, though care should be taken not to merge with neighboring structures. In preferred embodiments, at least one sub-layer of the barrier shell 8 is n-doped to enable modulation doping of the unintentionally doped layers 3, thereby enhancing electron transport along the sidewalls and bottom surfaces of the channel. The spacer layer may be composed of the widest-bandgap material to increase polarization and is generally placed in direct contact with the unintentionally doped layers 3. In some embodiments, elements such as scandium (Sc) or boron (B) are incorporated into the barrier shell 8 to further enhance polarization characteristics. Any dielectric masking layer can be fully removed following the formation of the barrier shell 8.

For improved contact resistance throughout the channel region, certain embodiments incorporate a selective regrowth step to form an extended source 9 and extended drain 10. This regrowth may employ dielectric masking or a similar technique to prevent deposition within the channel region, resulting in an n-doped layer grown on both sides of the source 6 and drain 7. By including the extended source 9 and extended drain 10 to encompass all unintentionally doped layers 3, the approach enhances electrical contact and overall device performance. In a preferred embodiment, the extended source 9 and extended drain 10 are formed from n-type GaN, although other III-Nitride materials may also be used. Doping levels may be greater than 1×10\hat{ }19 cm\hat{ }−3 for low resistivity. Any dielectric masking layer can be fully removed following the regrowth process.

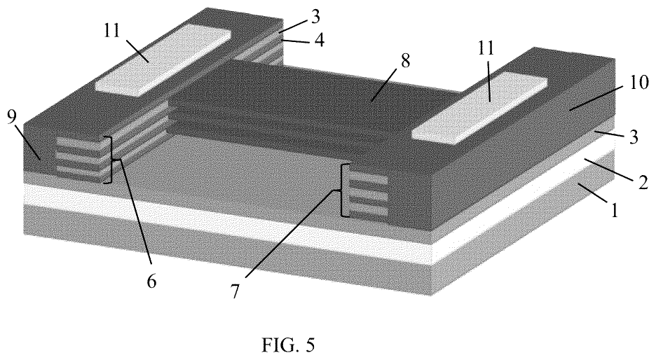

Ohmic contacts 11 to the source 6 and drain 7 on the initially etched structure or on the selectively regrown n-doped extended source 9 and extended drain 10 regions may be formed. In other embodiments the ohmic contacts 11 can be further extended to the channel region 5 to overlap the barrier shell 8. By way of example, low work-function metals such as titanium (Ti) and aluminum (Al) based materials may be used in part to form these contacts, followed by thermal annealing to further reduce contact resistance. FIG. 5 depicts a perspective view of the device structure after metallization of the source 6 and drain 7, including the selectively regrown n-doped extended regions.

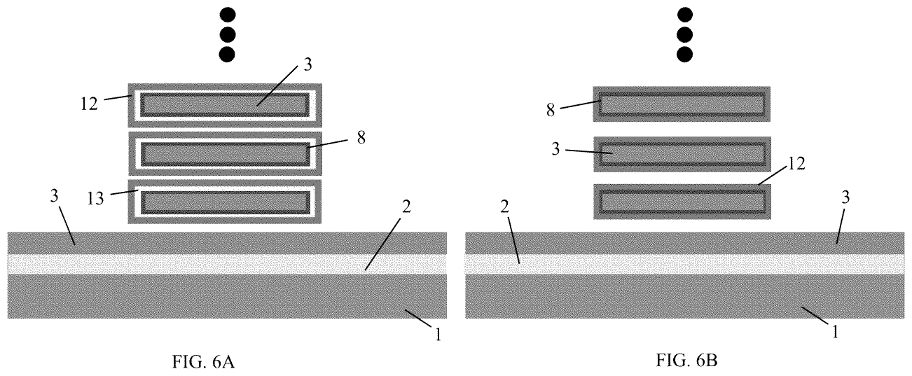

Referring now to FIGS. 6A-6B, cross-sectional views of the channel region 5 show the formation of the gate 12. In FIG. 6A, a dielectric layer 13 is deposited or otherwise grown around each unintentionally doped layer 3, thereby forming a gate dielectric. This dielectric layer 13 can be 3 to 30 nm thick in some examples, and comprise materials such as Al2O3, Si3N4, SiO2, or HfO2. A metal or semiconductor layer is subsequently formed around the dielectric 13 to create the gate 12. In contrast, FIG. 6B illustrates an embodiment wherein the dielectric layer 13 is omitted, and a Schottky gate contact is directly established as the gate 12 on the barrier shell 8. In the Schottky configuration, the work function of the gate metal or semiconductor material is selected to form a desired Schottky barrier at zero bias. Example choices for a Schottky gate can include high work function metals such as Ni, Pt, and Pd. In example implementations, the gate 12 and optional dielectric 13 can extend the length of the channel region 5, or just a portion.

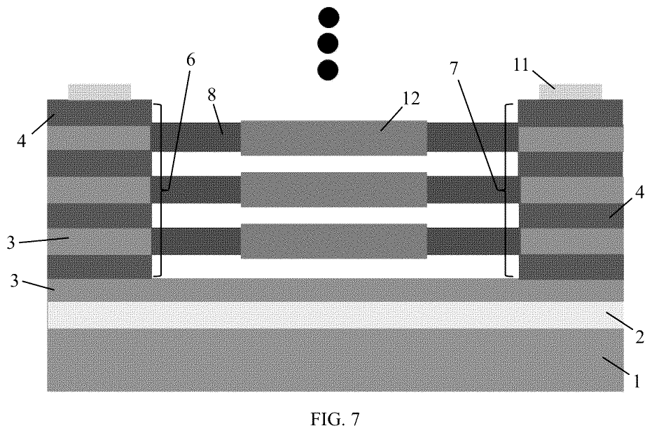

A 90-degree rotated cross-sectional view of FIGS. 6A-6B is shown in FIG. 7. In this implementation, the barrier shell 8 extends along the entire channel region, while the gate 12 (and optional dielectric 13) covers a portion of that length.

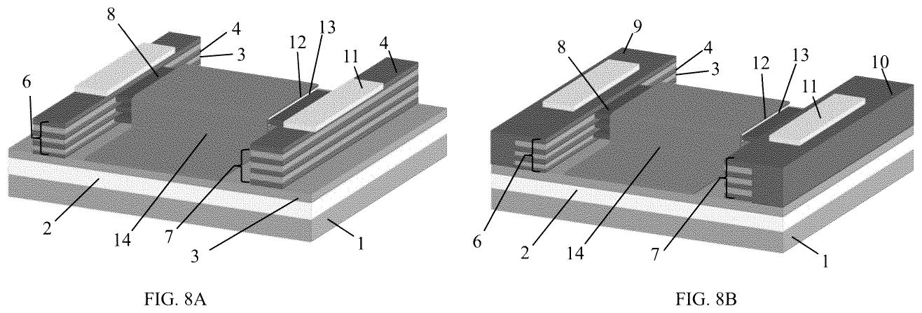

In order to provide both parallel control of the channel region 5 and external electrical connections, an interconnecting gate metallization 14 is deposited. By way of example, FIGS. 8A-8B illustrate embodiments without and with the extended n-doped source 9 and drain 10, respectively. Depending on the desired device architecture, additional contacts may be formed to ohmic contacts 11, along with the interconnecting gate metallization 14, through further dielectric and metallization steps.

In operation, the final device is configured as a high electron mobility transistor (HEMT) offering enhanced performance and the ability to have normally-off operation. The gate-all-around structure wraps around channel region 5, confining the conduction path and improving electrostatic control. This configuration enables sharper switching transitions, reduced short-channel effects, and enhanced threshold voltage stability. Additionally, the integrated barrier shell 8 can provide a modulation doping mechanism, improving channel conductivity and transconductance while maintaining low leakage. The optional regrown extended source 9 and extended drain 10 further lower contact resistance, thereby enhancing current drive capability. Collectively, these architectural innovations enable robust device operation across a wide range of power and high-frequency applications.

Accordingly, as illustrated and described by way of the examples herein, this technology provides a number of advantages including providing improved electrostatic gate control, the ability to have normally-off operation for enhanced safety, enhanced current density, reduced parasitic capacitance, and lower contact resistance. Moreover, the disclosed gate-all-around HEMT architecture supports scalability to nanoscale dimensions, facilitating higher integration densities and superior device performance in both power and radio-frequency circuits.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. A transistor device comprising:
a substrate;
a multi-layer structure formed on or above the substrate, the multi-layer structure including a plurality of repeated stacks, each stack comprising:
an n-doped III-Nitride layer, and
an unintentionally doped (u-doped) III-Nitride layer;
a channel region defined at least in part by one or more of the u-doped III-Nitride layers;
a barrier shell disposed around at least a portion of the channel region, wherein the barrier shell comprises a wider bandgap III-Nitride material relative to the u-doped III-Nitride layer;
a source and a drain region in electrical contact with the channel region; and
a gate structure configured to surround the channel region, forming a gate-all-around transistor configuration.

2. The transistor device of claim 1, wherein the transistor device is configured as a high electron mobility transistor (HEMT).

3. The transistor device of claim 1, further comprising a buffer layer between the substrate and the multi-layer structure.

4. The transistor device of claim 1, wherein the n-doped III-Nitride layer is doped with silicon at a concentration greater than approximately 1×10\hat{ }18 cm\hat{ }−3.

5. The transistor device of claim 1, wherein the barrier shell includes a spacer layer in direct contact with the u-doped III-Nitride layer, the spacer layer having the widest bandgap among layers of the barrier shell to enhance polarization effects.

6. The transistor device of claim 1, further comprising a selectively regrown n-doped material extending the source and drain regions to reduce contact resistance.

7. The transistor device of claim 1, wherein the barrier shell is configured to provide modulation doping of the u-doped III-Nitride layer in the channel region.

8. The transistor device of claim 1, wherein the channel region comprises a plurality of nanosheet or nanowire structures formed from the u-doped III-Nitride layers.

9. The transistor device of claim 1, wherein the barrier shell comprises an AlGaN, AlInGaN, or other III-Nitride alloy incorporating an element selected from the group consisting of Sc and B.

10. The transistor device of claim 1, wherein the gate structure further comprises:
a gate dielectric disposed around each barrier shell in the channel region; and
a gate electrode comprising a metal or semiconductor in contact with the gate dielectric, such that the gate electrode substantially encircles the channel region.

11. The transistor device of claim 1, wherein the gate structure forms a Schottky contact directly with the barrier shell, the work function of the gate material selected to achieve a normally-off operation at zero bias.

12. The transistor device of claim 1, further comprising a plurality of parallel u-doped III-Nitride columns in the channel region, each column having a respective gate-all-around structure, and wherein the source and drain regions are shared among the plurality of columns.

13. A transistor device comprising:
a substrate;
a plurality of columns formed above the substrate each comprising a repeated sequence of an n-doped III-Nitride layer and an unintentionally doped III-Nitride layer, wherein the unintentionally doped III-Nitride layer in each column defines at least part of a channel region;
a barrier shell disposed to surround at least part of each channel region, the barrier shell comprising a wider bandgap III-Nitride material configured to enhance electron confinement;
ohmic contacts formed on a source and a drain region that are electrically coupled to the channel region; and
a gate electrode configured to at least partially encircle each channel region, thereby forming a gate-all-around transistor configuration.

14. The transistor device of claim 13, wherein each column has a width dimension in a range of about 5 nm to about 1000 nm, thereby forming a nanosheet or nanowire channel.

15. The transistor device of claim 13, wherein the device is configured for normally-off operation such that no substantial current flows through the channel region when the gate electrode is at zero bias.

16. The transistor device of claim 13, wherein the transistor device is configured as a high electron mobility transistor (HEMT).

17. The transistor device of claim 13, further comprising a buffer layer between the substrate and the multi-layer structure.

18. The transistor device of claim 13, wherein the n-doped III-Nitride layer is doped with silicon at a concentration greater than approximately 1×10\hat{ }18 cm\hat{ }−3.

19. The transistor device of claim 13, wherein the barrier shell includes a spacer layer in direct contact with the u-doped III-Nitride layer, the spacer layer having the widest bandgap among layers of the barrier shell to enhance polarization effects.

20. The transistor device of claim 13, further comprising a selectively regrown n-doped material extending the source and drain regions to reduce contact resistance.
